(19) United States
(12) Patent Application Publication
(10) Pub. No.: US 2004/0199842 A1
(43) Pub. Date: Oct. 7, 2004

(54) Test system with high accuracy time measurement system

(76) Inventor: Ronald A. Sartschev, Dunstable, MA (US)

Correspondence Address: Legal Department, Teradyne, Inc., 321 Harrison Avenue, Boston, MA, 02118, US

(21) Appl. No.: 10/407,769

(22) Filed: Apr. 4, 2003

(51) Int. Cl. G01R 31/28; G06F 11/00

(52) U.S. Cl. 714/731

(57) ABSTRACT

An automatic test system for testing semiconductor devices. The test system includes time measurement circuitry. The time measurement circuitry can be programmed to operate in a single-shot mode or a higher resolution, repetitive-measurement mode. To simplify the design and construction of the system, the same time measurement circuit is used in both measurement modes. To provide higher resolution in the repetitive measurement mode, variation is introduced into the signal to be measured and resulting measurements are averaged. Any bias introduced by the variation is subtracted from the averaged value.

### CROSS-REFERENCES TO RELATED APPLICATIONS

Not Applicable.

### STATEMENT REGARDING FEDERALLY SPONSORED RESEARCH OR DEVELOPMENT

Not Applicable.

### REFERENCE TO MICROFICHE APPENDIX

Not Applicable

### BACKGROUND OF THE INVENTION

1. Field of the Invention

This invention relates generally to automatic test equipment and more specifically to automatic test systems that measure relative timing of signals.

2. Description of Related Art

Semiconductor chips are generally tested at multiple stages during their manufacture with automatic test equipment (ATE). To determine whether a chip is properly functioning, it is important to know the values of signals generated by the chip in response to various stimulus signals. In addition to the value, it is often important to know whether those signals occur at the expected time. Thus, ATE has traditionally included timing generation circuitry that controls when a stimulus is applied and when a measurement is made.

Traditional digital logic chips contain circuitry that is synchronized by a master clock signal. In testing digital logic chips, time is often relative to the cycles of a master clock signal. Thus, the timing generator creates signals, sometimes called “edge signals,” that have specified times relative to a cycle of a master clock signal. In most ATE systems, the time of each edge signal can be programmed so that the ATE can be used to test different kinds of chips or run different kinds of tests.

However, simply generating or measuring signals relative to a cycle of a master clock is sometimes not adequate to test a chip. More recently, chips have included analog and digital circuitry. The analog circuitry processes signals, such as audio or video signals. These signals have features that are often not synchronized to the master clock of the chip. Thus, to measure the timing of these signals, it is not adequate for ATE to generate edges relative to a master clock. Rather, some ATE includes a time stamp system.

A time stamp system generates a time tag that indicates when a particular signal occurs relative to some reference time. A very simple time stamp system is a counter. A reference signal starts the counter running. The event signal stops the counter. After the counter stops, its value can be read out and indicates the amount of time between the start and stop events.

The drawback of a simple counter is that it has limited resolution. Each count of the counter reflects the passage of time that is one period of whatever clock signal is running the counter. For example, if the counter is clocked by an 800 MHz signal, each count represents 1.25 nanoseconds. Regardless of the actual time being measured, a time measurement system that uses such a counter will report time based on the number of 1.25 nanosecond increments that have passed. The counter reveals that the event occurred in a time window 1.25 nanosecond long that is after a certain number of counts and before the next count. However, there is no way to distinguish between signals that happen early in that window or late in the window, so the resolution of the measurement is limited by the period of the clock.

Often, time measurement with a resolution limited by the period of the clock will not be adequate. Very often, resolution to within a fraction of a nanosecond is required for time measurements. Therefore, many time measurement systems include an “interpolator.” The interpolator measures time in the window between periods of the clock. One form of interpolator uses a ramp generator and an analog to digital converter. The clock signal triggers the ramp generator to start generating a signal. The ramp signal increases in value as time passes. The event signal stops the increase in the ramp signal and causes the A/D converter to measure the value of the ramp. The output of the A/D is proportional to the passage of time after the last clock pulse and indicates an additional time that should be added to the time measured by the counter.

A drawback of this approach is that the interpolator must be made with very stable circuitry. Variations in the delays introduced by the interpolator limit the accuracy of the measurements. For example, variations in delay can be caused by changes in operating temperature or other environmental factors. Thus, interpolators have traditionally been made of ECL components or other circuitry that has very little variation in delay. However, ECL components are expensive and not widely available.

Also, as a particular problem for ATE, we have recognized that use of ECL components for time measurement reduces the level of integration of the overall test system. Much of a test system is built with CMOS circuitry. CMOS circuitry is small, allowing for high levels of integration on a chip. ECL circuits are built using different processes than CMOS and will likely be on a separate chip. The extra chip, as well as the added space consumed by including I/O pads in the CMOS chips to connect to the ECL chip increases cost and reduces the level of integration of the overall test system. These problems are magnified in ATE because ATE generally consists of hundreds and sometimes thousands of channels in which separate signals are generated. Therefore, numerous copies of the chips will be required in each ATE system.

Further, ECL components consume relatively large amounts of power in comparison to CMOS. High power consumption is a drawback for circuitry in ATE. In ATE, it is desirable to get the circuits that must make accurate measurements physically as close to the chip under test as possible. Time measurement is one such circuit. However, if these circuits consume large amounts of power, they also generate large amounts of heat. Packing such chips close together results in a high heat density, which in turn creates a need for complicated cooling systems. Thus, using chips with higher power utilization has side effects that further increase the cost, size and complexity of ATE.

We have recognized that achieving a compact, low cost test system would need an accurate time stamp system that is low cost, compact and low power. Co-pending patent application U.S. Ser. No. 10/015,865 entitled Compact ATE with Time Stamp System by Sartschev et al. describes one such system and is hereby incorporated by reference.

It would be desirable to improve the resolution of a time stamp system without greatly increasing the size of the circuitry. Preferably, the resolution should be increased using simple changes in the system.

### BRIEF SUMMARY OF THE INVENTION

With the foregoing background in mind, it is an object of the invention to provide a time measurement system with increased resolution.

The foregoing and other objects are achieved in a time measurement system that has a controllable variation that can be added to the input signal. The controlled variation introduces a known bias into the time of the signal. Repetitive time measurements are made and average, and offset for the known bias.

In a preferred embodiment, the known bias is zero.

In the preferred embodiment, the time measurement system is part of an automatic test system and is implemented with CMOS circuitry.

Further according to the preferred embodiment, the system is implemented with circuitry that adds variation when repetitive measurements are to be made and averaged but has minimal impact on the input signal when single shot measurements are made.

### BRIEF DESCRIPTION OF THE DRAWINGS

Additional objects, advantages, and novel features of the invention will become apparent from a consideration of the ensuing description and drawings, in which—

FIG. 1 is a block diagram of an ATE system including time measurement systems;

FIG. 2 is a block diagram of a time stamp system modified according to the invention;

FIG. 3 is a high level schematic of the time stamp system of FIG. 2; and

FIGS. 4A, 4B and 4C are sketches showing waveforms on which time measurements might be made.

### DETAILED DESCRIPTION OF THE PREFERRED EMBODIMENT

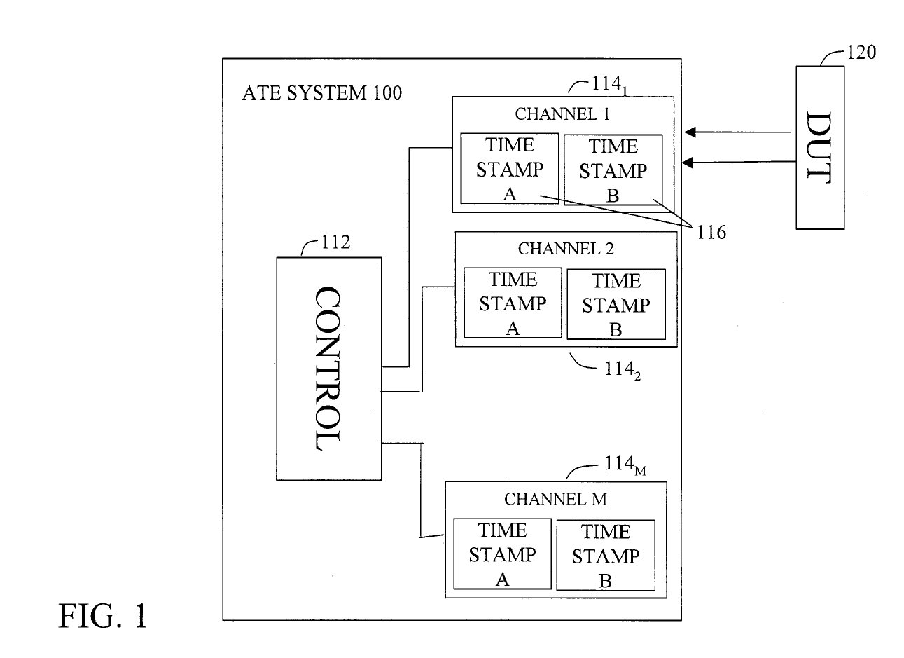

FIG. 1 is a block diagram of an automatic test system 100 using a time measurement system according to the invention. ATE system 100 tests a device under test (DUT) 120. In the illustrated embodiment, DUT 120 is a semiconductor device. For example, DUT 120 could be a modem chip that should, if functioning properly, generate a pulse of a particular shape at a certain time after a digital input signal is applied.

As is known in the art, ATE 100 has a plurality of channels 114₁ . . . 114_{M}. Each channel can generate and measure a signal that is supplied to or received from DUT 120. The channels operate under control of control circuitry 112. Preferably, control circuitry 112 is implemented primarily as one or more CMOS integrated circuits. To decrease the size and cost of the overall system, as much as possible of the circuitry in each channel is also implemented in CMOS integrated circuits.

As in a conventional test system, each of the channels can generate and measure independent signals. Preferably, each channel can generate or measure a digital signal at a programmed time. In addition, each channel 114₁ . . . 114_{M} is shown to include time stamp circuits 116. Each time stamp circuit can measure the time of occurrence of a signal relative to a reference time. Two time stamp circuits are included in each channel in the illustrated embodiment to allow one time stamp circuit to measure the relative time of a signal event indicating the start of some interval and the other can measure the relative time of a signal event indicating the end of an interval. In that way, the length of the interval can be measured by taking the difference of the starting and ending times of the interval.

In the preferred embodiment, each time stamp circuit 116 is implemented as CMOS integrated circuits. A suitable circuit is described in the above mentioned patent application U.S. Ser. No. 10/015,865 entitled Compact ATE with Time Stamp System by Sartschev et al. In a commercial embodiment, each of the time stamp circuits 116 can measure times with a resolution of 8 psec.

For many types of semiconductor DUTs, a resolution of 8 psec is adequate for time measurements. Jitter, noise and other factors will limit the accuracy of a measurement on a single event to approximately 40 psec and there is little benefit to having a resolution that is higher than the accuracy of the measurements. Such measurements are sometimes called “single-shot” measurements.

However, in testing certain types of DUTs, the DUT is controlled to generate the same type of signal repetitively. For each repetition, the timing of the same signal event is measured. These measurements are averaged. As is known, averaging multiple measurements reduces the measurement error caused by random variations in proportion to the square root of the number of measurements included in the average. Such measurements are called “repetitive measurements.” Where repetitive measurements are made, the accuracy is better and it is desirable to have a better resolution. Accordingly, in the preferred embodiment of automatic test equipment for semiconductor devices, the resolution of time measurements is preferably below 8 psec. More preferably, it is below 4 psec. Most preferably, it will be around 1 psec.

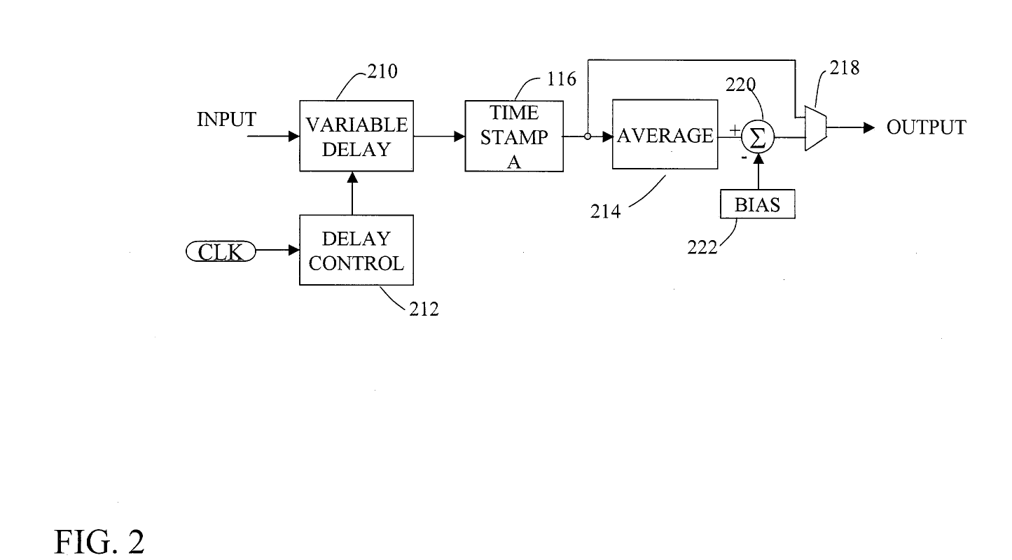

FIG. 2 illustrates circuitry to increase the resolution of time measurements for repetitive measurements without significantly increasing the size, complexity or cost of the time stamp circuitry.

FIG. 2 shows a time stamp circuit 116. Time stamp circuit 116 is preferably a CMOS based timing circuit and is, in a preferred embodiment, a circuit as described in patent application U.S. Ser. No. 10/015,865 entitled Compact ATE with Time Stamp System by Sartschev et al. However, any prior art time measurement circuit could be used.

The INPUT signal to the time measurement circuit is passed through variable delay 210. The amount of delay introduced by variable delay 210 is controlled by delay control 212. In the described embodiment, the amount of delay varies between 0 and the resolution of time stamp circuit 116.

Delay control 212 changes the amount of delay added to the INPUT signal such that for different measurements in a repetitive measurement set different amounts of delay are introduced. The average amount of delay introduced by delay control 212 and variable delay 210 should be known. One way that the average amount of delay can be known is to have delay control 212 provide a deterministic output, which has a predetermined average. A second way to achieve a known average value is to have delay control 212 provide a random or pseudo random output signal with known or measured statistical properties. In the illustrated embodiment, a deterministic signal will be described.

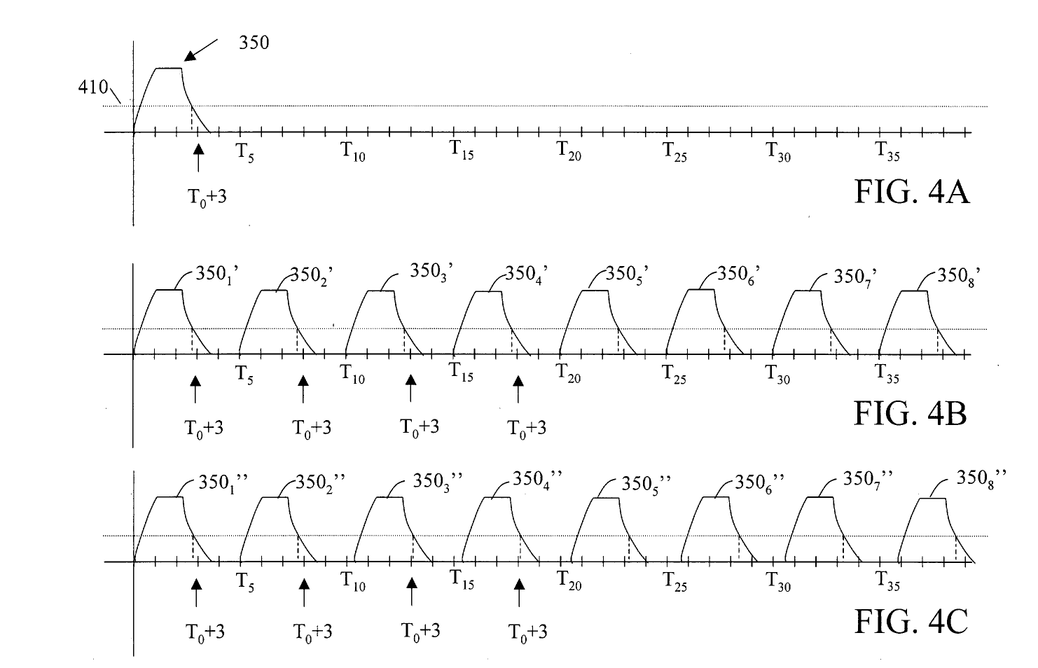

The CLK input to delay control 212 causes the amount of delay introduced at any given time to change periodically. The invention will be illustrated with a circuit that has delay values that change at discrete intervals. The precise time at which the delay values change is not critical to the invention. However, the changes should be frequent enough that for a set of repetitive measurements, the individual measurements are made with many different delay values. Repetitive time measurements of an event in a signal are passed to an averaging circuit 214. The precise construction of the averaging circuit is not critical to the invention. However, a simple averaging circuit can be implemented with an accumulator. If the number of repetitive time measurements can be expressed as 2^{N} the accumulated value can be converted to an average by simply down-shifting by N bits. It should be noted that the averaged value will therefore have more bits of resolution than the time measurements. The reason why this averaging of measurements results in greater resolution will be explained below in connection with FIGS. 4A and 4B.

Other averaging circuits can be constructed for cases where the number of measurements can not be expressed as a power of 2. For example, a digital divider might be used.

Where a variable delay has been introduced, the output of averaging circuit 214 represents the average time measurement plus the average of the delay that has been introduced. Thus, the measurement has been biased by the average value of the delay that has been added. Thus, averaging circuit 214 is shown followed by an summing circuit 220 that subtracts off this bias.

It should be appreciated by one of skill in the art that summing circuit 220 could be implemented as a separate physical circuit from the averaging circuit 214. However, it might also be implemented with control logic that loads a negative value into an accumulator that is part of averaging circuit 214. Any other convenient circuit implementation could be used.

In cases where a single-shot measurement is desired, there is no benefit to adding any delay to the INPUT signal. Thus, it is preferably for single shot measurements that delay control 212 add no delay to the signal and average circuit 214 be by-passed. Multiplexer 218 allows averaging circuit 214 to be by-passed when not needed, such as for single-shot measurements. Control signals for multiplexer 218 are not expressly shown. However, it should be appreciated that control circuit 112, preferably operating under software control, generates the appropriate control signals in any convenient manner.

Thus, the circuitry shown in FIG. 2 can be used increase the resolution where averaging of repetitive measurements allows for more accurate measurements. In cases where a single-shot measurement is made, and averaging will not increase the accuracy of the measurement, so no greater precision is required and the circuit does not interfere with the time measurement.

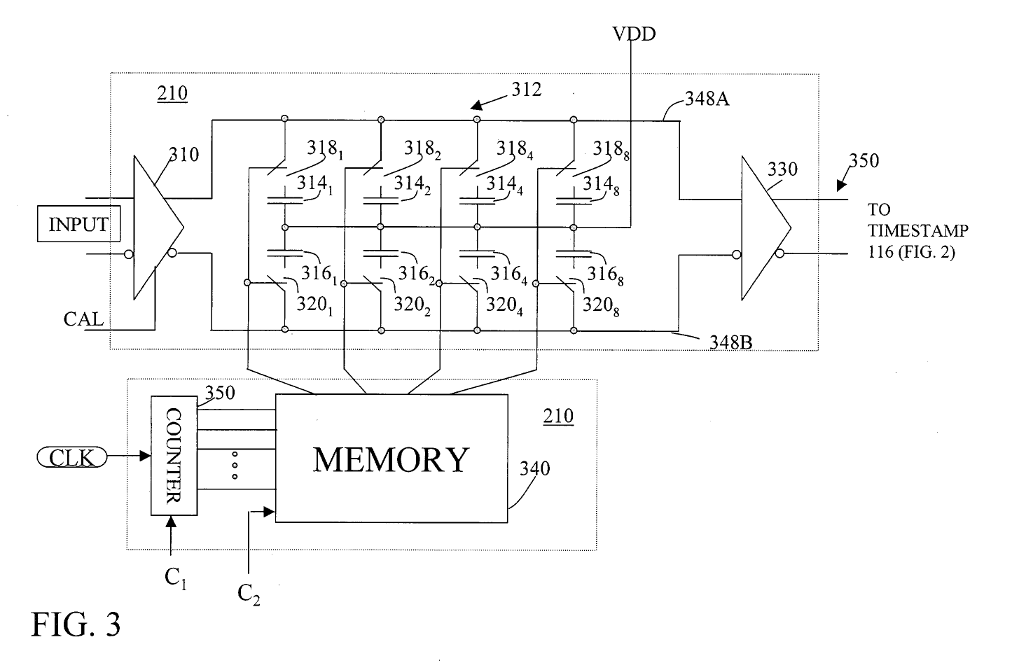

Turning now to FIG. 3, further details of the presently preferred embodiment of variable delay 210 and delay control 212 are shown. In the illustrated embodiment, the INPUT signal is represented as a differential signal—meaning that the signal is represented as the difference in voltage levels between two lines.

Variable delay has an input buffer amplifier 310 and an output buffer amplifier 330. The differential signal runs on lines 348A and 348B between the input and output buffers.

A plurality of capacitors can be switchably connected between the lines 348A and 348B. As more capacitance is added to the signal lines, the propagation time between input buffer amplifier 310 and an output buffer amplifier 330 decreases. Thus, the delay through delay element 210 can be controlled by controlling the capacitance switched onto the lines 348A and 348B.

To control the capacitance on lines 348A and 348B, switches 318₁, 318₂, 318₄, 318₈, 320₁, 320₂, 320₄, and 320₈ can be opened or closed. Each switch, when closed, connects a capacitor to one of the signal lines 348A or 348B.

In the differential signal embodiment illustrated, the capacitors are arranged in pairs of capacitors. Capacitors 314₁ and 316₁ are paired, as are 314₂ and 316₂, 314₄ and 316₄ and 314₈ and 316₈. Preferably, each capacitor in a pair is sized to introduce the same amount of delay onto its respective line 348A or 348B. In an ideal implementation, the circuitry would be symetrical and both capacitors in a pair would be the same size. In an actual implementation, it is possible that buffers 310 and 330 will not be exactly symmetrical and, to be matched, the capacitors in each pair might have slightly different values.

In the illustrated embodiment, each of the pairs of capacitors introduces a different amount of capacitance. Here, a binary weighting scheme is shown. 314₂ and 316₂ introduce twice as much delay as capacitors 314₁ and 316₁. Capacitors 314₄ and 316₄ introduce four times as much delay as capacitors 314₁ and 316₁. Capacitors 314₈ and 316₈ introduce eight times as much delay as capacitors 314₁ and 316₁.

By selectively connecting these capacitors to lines 384A and 384B, 16 different values of delay can be added. The amount of delay that can be added ranges from 0 (no capacitors connected) to 15 times the “unit delay” introduced by capacitors 314₁ and 316₁

In the preferred embodiment, the unit delay is one-sixteenth the resolution of the time stamp 116. State of the art CMOS time measurement circuitry that can be conveniently implemented in an automatic test system for semiconductor devices has a resolution of approximately 8 psec. Thus, the unit delay is about 0.5 psec.

FIG. 3 shows a CAL input to buffer 310. It is known that the delay through the same CMOS circuit can vary over time based on operating temperature. Delays can also vary from circuit to circuit based on normal variations in manufacturing process. Therefore, when CMOS is used in time critical circuits, the delay through each circuit is often calibrated.

Patent application U.S. Ser. No. 10/015,865 entitled Compact ATE with Time Stamp System by Sartschev et al. describes an approach to calibration. A delay locked loop made of CMOS components is controlled until the delay through the loop matches the period of a reference clock signal. The same control signal that is used to adjust the delay through the loop can be used to adjust the delay of other circuitry on the same chip.

The CAL signal shown in FIG. 3 can be derived from such a calibration circuit. If the buffer 310 is similar enough to the circuitry in the delay locked loop used to give the calibration values, the calibration signal can be used directly. However, it might be desirable to scale the calibration signal to make the calibration of buffer 310 more accurate. In addition to varying in relation to changes in operating temperature of the CMOS chip that contains delay 210, it is desirable that the output levels of amplifier 310 be such that, for whatever values of capacitance is used in variable delay 210, the desired delay is achieved.

Various types of calibration routines are known and the specific method of calibration is not important to the present invention. As one example, the scale factor might be determined by applying a signal of precise, known time characteristics as the input signal. The scale factor used to derive the CAL signal might be varied until the measurements match the known characteristics of the reference input signal. The scale factor would then be stored and used until the calibration routine was performed again.

The control lines that feed switches 318₁, 318₂, 318₄, 318₈, 320₁, 320₂, 320₄, and 320₈ can be thought of as a 4-bit word that specifies the amount of delay. The control line to switches 318, and 320, are the least significant bit of the control word. The control line to switches 3188 and 3208 are the most significant bit of the control word.

Delay control circuit 210 varies the amount of delay introduced by variable delay circuit 210 by changing this control word. In the illustrated embodiment the control signal is deterministic. A deterministic control signal can be generated according to a pattern stored in memory 340. In a preferred embodiment, the pattern stored in memory 340 varies the control word in a repetitive manner. In the presently preferred embodiment, the variation follows a generally sinusoidal pattern. However, other patterns could be used to increase the resolution of a repetitive time measurement.

Preferably, the frequency of repetition of the delay control signal is high enough that many variations of the control signal occur over the interval during which repetitive measurements are taken (the “data acquisition period”). To simplify the computation of the bias introduced by the variable delay, it is preferable that either an integer number of repetitions of the control signal occur over the data acquisition period or that a very large number of repetitions of the control signal, such as at least 10, occurs over the data acquisition period.

It is also preferable that the frequency of repetition be slower than the frequency of repetition of the frequency of repetition of the signal on which repetitive measurements are made. Preferably, the delay control signal will have a repetition frequency that is less than half that of the repetition rate of the signal being measured. However, it should be appreciated that improvements in the resolution of the measurement can be made even if these ratios between the repetition rate of the delay control signal and the signal being measured are not strictly met. Other ratios are suitable if the measured signal and the delay control signal not be synchronized.

To provide the flexibility needed for an automatic test system for semiconductor devices, the repetition rate of the control signal can be controlled through delay control circuit 210. In the illustrated embodiment, counter 350 generates the address signals to memory 340. When counter 350 overflows and returns to zero, the pattern output by memory 340 will begin another repetition. Thus, the rate of repetition of the delay control signal is set by how long it takes for counter 350 to cycle through its maximum count.

In the illustrated embodiment, counter 350 is a divide-by-N counter. The value of N is specified by control input C₁. In such a counter, the output advances by one for every N pulses of the input clock, CLK. Thus, the repetition rate of the control signal can be decreased by increasing the value of N. For example, in the preferred embodiment, the pattern of delay variation stored in memory 340 contains 64 sequential values. To provide address signals to memory 340 to successively select 64 values, counter 350 is an eight-bit counter. The period of repetition of the delay pattern is therefore computed by multiplying the period of clock signal, CLK, by whatever value of N is set by control input C₁.

For ease of implementation, the frequency of CLK is fixed, preferably in the range of 125 to 250 MHz. Also, the number of values in the delay pattern will also be fixed. In use, the only value that will change is the value of N set by control input C₁. A user will specify this value of N. The user might specify the value of N directly. Or, for greater user convenience, the user might provide information about the signals to be measured and controlling software would automatically select a value of N.

As described above, the delay control signal has a sinusoidal pattern. The described embodiment allows the pattern of variation in the control signal to be changed. One way that the pattern of variation might be changed is by simply loading different values into memory 340. Where it is likely that different values might be used, memory 340 is preferably implemented as a RAM that can be reprogrammed according to software or other programatic instructions provided by a user of the test system.

An alternative way to change the pattern of the variation might be through the use of control signal C₂. Control signal C₂ is shown connected to an address line of memory 340. In this way, it acts as a “page control.”

In the illustrated embodiment, one of the pages accessed by control signal C₂ corresponds to zero delay values. In this way, the circuitry added to increase the resolution of repetitive measurements could be simply controlled to have no impact on single-shot measurements.

Turning now to FIG. 4A, operation of the circuit in FIGS. 2 and 3 is illustrated. FIG. 4A shows a signal 350. The time axis in FIG. 4A is gradated in increments that match the resolution of time stamp circuit 116. Because the time stamp circuit 116 can only measure time with a resolution that matches the gradations, the time measurement will be reported only as an integer number of gradations.

For the example of FIG. 4, the signal event is the falling edge of the signal crossing a threshold 410. As can be seen in FIG. 4A, the signal event crosses the threshold slightly before the time indicated as T₀+3. However, because the time will be reported as an integer number of gradations, the time will be reported as 2 gradations. Or, in the example where time stamp circuit 116 has a resolution of 8 psec, the time of the event will be reported as 16 psec. It can be seen, though, that the time of the event is actually much closer to 24 psec, approximately 22 psec. However, because the resolution of the measurement is limited, a more accurate measurement is not possible.

FIG. 4B shows essentially the same waveform, but occurring as a repetitive waveform. For each repetition, 350₁′, 350₂′ . . . 350₈′ the same measurement is repeated. In an ideal environment where no noise is introduced, the measurement is the same each time. Essentially, for each repetition, the time is measured as two gradations. Averaging the measurements across the multiple repetitions results in the average value being two gradations—or 16 psec in this example. The averaging might eliminate the effect of noise, but would not increase the resolution of the measurements.

Turning now to FIG. 4B, the same waveform is shown, but with variable delay 210 in place. In the illustrated embodiment, half the period of the variation of the delay equals the time it takes for eight repetitions 350₁″, 350₂″ . . . 350₈″. As can be seen, zero delay is introduced on the first repetition, 350₁″. However, by the eighth repetition, the signal is delayed an amount equal to fifteen sixteenths of a gradation. For simplicity, the next eight repetitions of the signal are not shown. Those repetitions would look similar to those shown, but with delays decreasing from almost one gradation back to no delay.

For the first repetition of the signal, 350₁″, the time measurement is the same as for the single-shot measurement of FIG. 4A. For the second repetition of the signal, 350₂″, the time of the event has been shifted, but not enough to change the time measurement. However, by the third repetition of the signal, 350₃″, the time of the event has been shifted enough to cross the next gradation. Thus, the measured time for the third repetition is three gradations—or 24 psec. For the next five repetitions, the signal has been shifted sufficiently to result in a measurement of 24 psec.

When the measurements over eight repetitions are averaged, the result is 22 psec. As can be seen in FIG. 4, the averaged measurement is closer to the actual time value of the event being measured. Also, the averaged value is not an integer multiple of the gradations at which time stamp 116 can make measurements. Thus, the measurement is made with a higher resolution than the underlying circuitry.

Because the variable delay signal causes the measured value to fall above or below the actual value, the delay is not introducing any bias into the signal measurement. However, depending on the construction of the measurement circuitry a bias might be introduced, which would later need to be subtracted to achieve an accurate measurement.

Alternatives

Having described one embodiment, numerous alternative embodiments or variations can be made.

For example, it is described that a “page control” signal is used to cause variable delay 210 to generate control signals to introduce zero delay values. However, it should be appreciated that other methods might be used to inhibit the introduction of delay, including other techniques to set the delay control signal to zero.

Also, it was described that a CAL signal is used to ensure that the delay introduced by the variable delay introduces a known bias into the time measurements. Alternatively, rather than using calibration to adjust the characteristics of the delay that is introduced, the actual characteristics of the delay introduced might be measured. In this case, the calibration would be used to change the bias adjustment.

While the invention has been particularly shown and described with reference to the preferred embodiments thereof, it will be understood by those skilled in the art that various changes in form and detail may be made therein without departing from the spirit and scope of the invention.

Also, it was described that repetitive measurements are averaged. Averaging might be thought of as a form of low pass filtering. Preferably, the low pass filtering will be performed using digital signal processing. However, comparable functions could be performed with analog circuitry.

What is claimed is:

1. A method of operating an automatic test system of the type having a time measurement circuit characterized in that the time measurement circuit has a mode of operation for repetitive events to increase the resolution of the time measurements comprising:
a) introducing time variation into the signal before measuring the timing of an event within the signal;
b) repetitively measuring the timing of the event within the signal;
c) averaging the time measurements to thereby determine the timing of the event in a resolution greater than the resolution of the time measurements.

2. The method of operating an automatic test system of claim 1 additionally comprising disabling the introduction of variation into the signal when making a single shot measurement.

3. The method of operating an automatic test system of claim 1 wherein the measuring the timing of an event within the signal is performed with circuitry in a CMOS integrated circuit.

4. The method of operating an automatic test system of claim 3 wherein introducing variation into the signal is controlled by CMOS circuitry in the CMOS integrated circuit.

5. The method of claim 1 wherein the introduced variation adds a known bias to the signal and the step of determining the timing of the event comprises subtracting the known bias from the average of the time measurements.

6. The method of claim 1 wherein introducing variation comprises passing the signal through a variable delay element and varying the delay of the delay element.

7. The method of claim 6 wherein the variable delay element comprises a plurality of capacitors switchably coupled to the signal path and the delay is varied by altering the number of capacitors switched to the signal path.

8. The method of claim 6 wherein the delay through the delay element is varied by a control signal generated by retrieving values from a memory circuit.

9. The method of claim 6 wherein the variable delay is a differential delay.

10. The method of claim 9 wherein the variable delay comprises an input buffer and an output buffer amplifier, with a pair of signal lines running therebetween with a plurality of pairs of matched capacitors, with a capacitor in each of the pairs switchably connectable to one of the signal lines in the pair.

11. The method of claim 1 used to manufacture semiconductor chips,
a) wherein the signal is generated by a semiconductor chip being manufactured; and
b) the method additionally comprises:
i) comparing the determined timing of the signal to a predetermined value;
ii) selecting additional processing steps to be performed on the semiconductor chip in response to the comparison made on the determined timing.

12. An automatic test system of the type having a time measurement circuit characterized in that the time measurement circuit has a mode of operation for repetitive events to increase the resolution of the time measurements, operated according to a method comprising:
a) introducing time variation into the signal before measuring the timing of an event within the signal;
b) repetitively measuring the timing of the event within the signal;
c) averaging the time measurements to thereby determine the timing of the event in a resolution greater than the resolution of the time measurements.

13. The automatic test system of claim 12 operated according to a method additionally comprising disabling the introduction of variation into the signal when making a single shot measurement.

14. The automatic test system of claim 12 comprising a CMOS integrated circuit adapted to measure the timing of an event within the signal.

15. The automatic test system of claim 14 wherein circuitry within the CMOS integrated circuit is adapted to introduce variation into the signal.

16. The automatic test system of claim 12 additionally comprising a variable delay element adapted for introducing variation into the signal.

17. The automatic test system of claim 16 wherein the variable delay element comprises a plurality of capacitors switchably coupled to the signal path and the delay is varied by altering the number of capacitors switched to the signal path.

18. The automatic test system of claim 16 wherein the delay through the delay element is varied by a control signal generated by retrieving values from a memory circuit.

19. A CMOS integrated circuit chip adapted to increase the resolution of repetitive measurements in an automatic test system, comprising:
a) a time stamp circuit having an input and an output, the output representing time measurements with a first predetermined resolution;
b) a variable delay element connected to the input of the time stamp circuit;
c) an averaging circuit connected to the output of the time stamp circuit having an input coupled to the output of the time stamp circuit and an output providing time measurements with a second resolution, greater than the first predetermined resolution.

20. The CMOS integrated circuit chip of claim 19 additionally comprising a delay control circuit having an output coupled to and controlling the variable delay element, the delay control circuit generating as an output a periodic signal.
